(19) United States
(12) Patent Application Publication
(10) Pub. No.: US 2023/0290846 A1
(43) Pub. Date: Sep. 14, 2023

(54) SEMICONDUCTOR DEVICE AND METHOD FOR FABRICATING OF THE SAME

(71) Applicant: SK hynix Inc., Gyeonggi-do (KR)

(72) Inventor: Jun Sik KIM, Gyeonggi-do (KR)

(21) Appl. No.: 17/897,622

(22) Filed: Aug. 29, 2022

(30) Foreign Application Priority Data
Mar. 8, 2022 (KR) 10-2022-0029233

(51) Int. Cl. H01L 29/423; H01L 27/108; H01L 29/40; H01L 21/762

(52) U.S. Cl. CPC H01L 29/4236; H01L 27/10814; H01L 27/10885; H01L 27/10891; H01L 27/10876; H01L 27/10823; H01L 29/401; H01L 21/76237

(57) ABSTRACT

An embodiment of the present invention provides a method of fabricating a semiconductor device capable of relieving a dangling bond. The semiconductor device comprises a device isolation layer defining a plurality of active regions in a substrate, the device isolation layer including a first region where the active regions are spaced apart from each other at a first interval along a first direction and a second region where the active regions are spaced apart from each other at a second interval along the first direction, the second interval being wider than the first interval; a gate trench extending in the first direction to cross the active regions and the device isolation layer; and a buried gate structure gap-filling the gate trench, wherein a portion of the device isolation layer includes an air gap acting as a hydrogen pocket in a lower portion.

### CROSS-REFERENCE TO RELATED APPLICATIONS

The present application claims priority to Korean Patent Application No. 10-2022-0029233, filed on Mar. 8, 2022, which is incorporated herein by reference in its entirety.

### BACKGROUND

### 1. Field

The present invention relates to a semiconductor device and method for fabricating the same, and more particularly, to a semiconductor device having a buried gate and a method for fabricating the same.

### 2. Description of the Related Art

In order to improve the degree of integration of semiconductor devices, semiconductor devices having a structure in which word lines are buried in a substrate are under research.

### SUMMARY

An embodiment of the present invention provides a method of fabricating a semiconductor device capable of relieving a dangling bond formed at an interface between a substrate and a gate insulating layer.

According to an embodiment of the present invention, a semiconductor device comprises: a device isolation layer defining a plurality of active regions in a substrate, the device isolation layer including a first region where the active regions are spaced apart from each other at a first interval along a first direction and a second region where the active regions are spaced apart from each other at a second interval along the first direction, the second interval being wider than the first interval; a gate trench extending in the first direction to cross the active regions and the device isolation layer; and a buried gate structure gap-filling the gate trench, wherein the second region of the device isolation layer includes an air gap in a lower portion.

According to an embodiment of the present invention, a semiconductor device comprises: a substrate including an active region defined by device isolation layers; a gate trench formed both in the active region and the device isolation layer; and a buried gate structure gap-filling the gate trench, wherein the device isolation layer includes an air gap disposed at a lower level than the buried gate structure.

According to an embodiment of the present invention, a method of fabricating a semiconductor device comprises: forming a device isolation layer defining a plurality of active regions in a substrate, the device isolation layer including a first region where the active regions are spaced apart from each other at a first interval along a first direction and a second region where the active regions are spaced apart from each other at a second interval along the first direction, the second interval being wider than the first interval; forming a gate trench extending in the first direction to cross the active regions and the device isolation layer; and forming a buried gate structure gap-filling the gate trench, wherein the second region of the device isolation layer includes an air gap in a lower portion.

The present technology has the effect of improving the reliability of the semiconductor device by increasing the hydrogen passivation efficiency.

The present technology can form an asymmetric fin to increase the gate channel length and reduce the passing gate area to reduce interference between neighboring cells.

These and other features and advantages of the present invention will become apparent from the following description of detailed embodiments of the invention.

### BRIEF DESCRIPTION OF THE DRAWINGS

FIG. 1 is a plan view of a semiconductor device according to an embodiment of the present invention.

FIGS. 2A and 2B are cross-sectional views of a semiconductor device according to an embodiment of the present invention.

FIGS. 3A to 3L are cross-sectional views illustrating a method of fabricating a semiconductor device taken along line A-A′ of FIG. 1.

FIGS. 4A to 4L are cross-sectional views illustrating a method of fabricating a semiconductor device taken along line B-B′ of FIG. 1.

### DETAILED DESCRIPTION

Various embodiments described herein will be described with reference to cross-sectional views, plan views and block diagrams, which are ideal schematic views of the present invention. Therefore, the structures of the drawings may be modified due to fabricating technology and/or tolerances. Accordingly, various embodiments of the present invention are not limited to the specific structures shown in the drawings, but include any changes in the structures that may be produced according to the fabricating process. Therefore, any regions and shapes of regions illustrated in the drawings have schematic views, are intended to illustrate specific examples of structures of regions of the various elements, and are not intended to limit the scope of the invention. Sizes and relative sizes of components shown in the drawings may be exaggerated for clarity of description. Like reference numerals refer to like elements throughout, and “and/or” includes each and every combination of one or more of the recited items.

Reference to an element or layer “on” or “over” another element or layer includes not only the case where an element or layer is directly on the other element or layer, but also the case where an element or layer intervenes with other layers or elements. The terminology used herein is for the purpose of describing the embodiments and is not intended to limit the present invention. In this specification, the singular also includes the plural unless otherwise specified in the phrase.

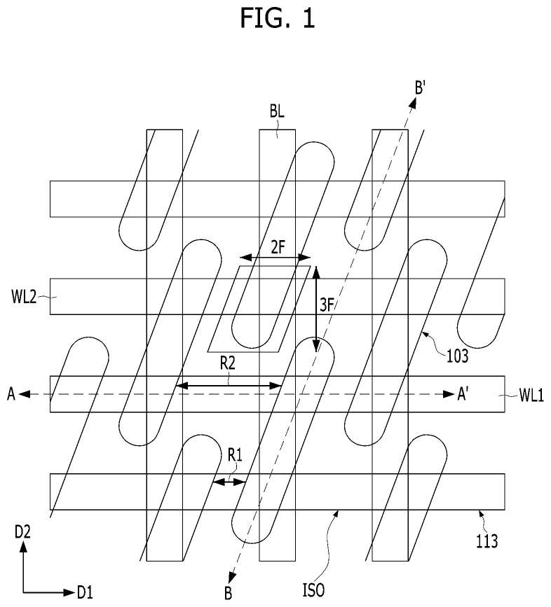

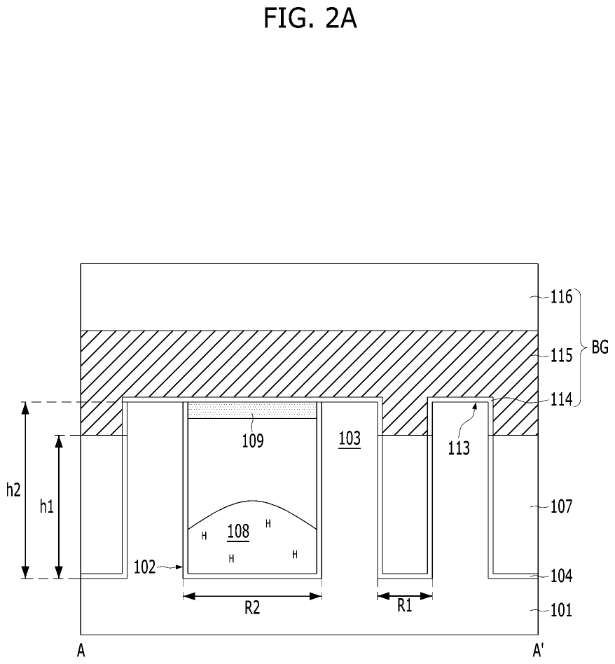

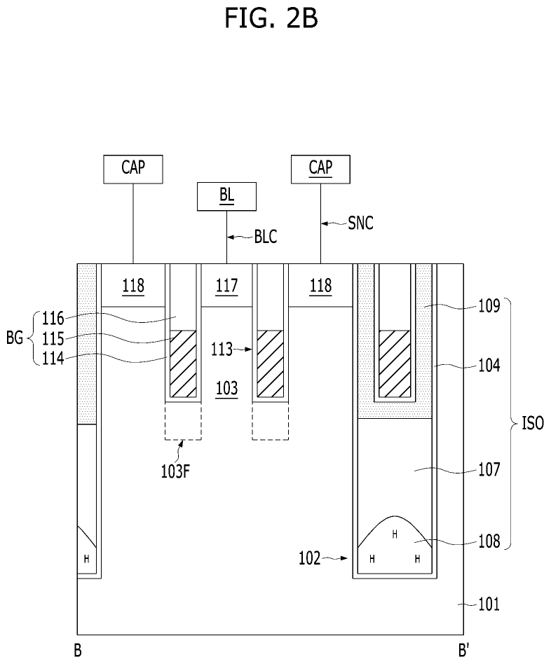

FIG. 1 is a plan view of a semiconductor device according to an embodiment of the present invention. FIGS. 2A and 2B are cross-sectional views of a semiconductor device according to an embodiment of the present invention. FIG. 2A is a cross-sectional view taken along line A-A′ of FIG. 1, and FIG. 2B is a cross-sectional view taken along line B-B′ of FIG. 1.

As shown in FIGS. 1, 2A and 2B, the semiconductor device according to an embodiment of the present invention may include a substrate 101. The substrate 101 may include a plurality of active regions 103 and an isolation layer ISO defining the active regions 103. In particular, a partial region of the device isolation layer ISO according to the embodiment may include an air gap 108 acting as a hydrogen pocket at the bottom thereof.

The substrate 101 may be a semiconductor substrate. The substrate 101 may be a silicon substrate, a germanium substrate, or a silicon-germanium substrate. The substrate 101 may include a memory cell array region in which memory cells are formed and a peripheral circuit region in which peripheral circuits for operating the memory cells are formed.

The active regions 103 may have a major axis and a minor axis, and may be disposed to be spaced apart from each other in the major axis direction and the minor axis direction. For example, the active region 103 may have a bar shape having a length longer than a width, and may be arranged in an island shape.

The device isolation layer ISO may be formed in the substrate 101. The device isolation layer ISO may define a plurality of active regions 103. The device isolation layer ISO may include isolation trench 102 formed in the substrate 101 and at least one insulating material gap-filled in the isolation trench 102. The device isolation layer ISO may include a first region R1 in which the active regions 103 are spaced apart at a first interval along the first direction D1 and a second region R2 in which the active regions 103 are spaced apart at a second interval along the first direction D1. The second interval may be wider than the first interval.

In an embodiment, the device isolation layer ISO may include a first and a second insulating material. The first insulating material may be for gap-filling the first region R1 and the second insulating material may be for gap-filling the second region R2. The first region R1 of the device isolation layer ISO may include a liner oxide layer 104 covering the sidewalls and bottom surfaces of the isolation trench 102 and a gap fill oxide layer 107 gap-filling the isolation trench 102. The second region R2 of the device isolation layer ISO may include a liner oxide layer 104 covering the sidewalls and bottom surfaces of the isolation trench 102, a gap-fill oxide layer 107 gap-filling a portion of the isolation trench 102, an air gap 108 formed between a bottom surface of the isolation trench 102 and the gap-fill oxide layer 107, and an isolation capping layer 109 that gap-fills the remainder of the isolation trench over the gap-fill oxide layer 107. For example, the isolation capping layer 109 may include silicon nitride.

In particular, in this embodiment, the air gap 108 may function as a hydrogen pocket. Hydrogen in the air gap 108 can increase the efficiency of a hydrogen passivation process by supplying hydrogen to the surface of the substrate 101. Specifically, hydrogen from the air gap 108 diffuses toward the substrate 101 during the hydrogen passivation process, and the diffused hydrogen may cure a dangling bond at the interface between the substrate 101 and the gate insulating layer 114.

Word lines WL1 and WL2 (or WL) may extend in a first direction D1 crossing the active regions 103, and the bit lines BL may extend in a second direction D2 crossing the first direction D1. The first direction D1 and the second direction D2 may cross vertically.

The active regions 103 are arranged to be tilted at a predetermined angle with respect to the word lines WL and the bit lines BL, so that one active region 103 may be formed to cross with two word lines WL and one bit line BL as is illustrated in FIG. 1. Accordingly, one active region 103 has a structure of two unit cells, and one unit cell has a length of 2F in the first direction D1 and a length of 3F in the second direction D2 based on the minimum feature size, so that the area of unit cell is 6F2. Here, F is the minimum feature size.

According to the 6F2 cell structure, the word line WL and the bit line BL cross each other vertically, and the active regions 103 is tilted in a diagonal direction with respect to the word line WL and the bit line BL are tilted. This structure is advantageous because it reduces the cell area. The semiconductor device according to an embodiment of the present invention is not limited to the described 6F2 cell structure only, but includes any cell structure falling within the scope of the present invention which decreases the cell area and improves the degree of integration of the semiconductor device.

The gate structures BG include gate trenches 113 formed in the substrate 101, gate insulating layers 114 uniformly formed on inner walls of the gate trenches 113, and a gate electrode 115 filling a portion of the gate trenches 113, and a gate capping layer 116 filling the remainder of the gate trenches 113 over the gate electrode 115. In this embodiment, the gate electrode 115 indicates a cross-section of the word line WL, and the gate electrode 115 and the word line WL indicate the same area.

Since the word line WL is formed of buried gate lines, a buried channel transistor may be implemented. The buried channel transistor may reduce a unit cell area and increase an effective channel length compared to a planar transistor. In the buried channel transistor, the capacitance between the word line WL and the bit line BL and the total capacitance of the bit line BL can be lowered to reduce parasitic capacitance since the word line WL is buried in the substrate 101.

The gate trench 113 may extend in the first direction D1. The gate trench 113 may cross the active region 103 and the device isolation layer ISO in the first direction D1. The device isolation layer ISO positioned under the gate trench 113 may have different heights in the first region R1 and the second region R2. The device isolation layer ISO under the gate trench 113 may have a height h1 in the first region R1 which is smaller than a height h2 in the second region R2. The upper surface of the first region R1 of the device isolation layer ISO under the gate trench 113 may be located at a level lower than the upper surface of the active region 103 under the gate trench 113. The upper surface of the second region R2 of the device isolation layer ISO under the gate trench 113 may be located at the same level as the upper surface of the active region 103 under the gate trench 113.

In another embodiment, an upper surface of the second region R2 of the device isolation layer ISO under the gate trench 113 may be located at a higher level than the upper surface of the active region 103 under the gate trench 113. In another embodiment, an upper surface of the second region R2 of the device isolation layer ISO under the gate trench 113 may be located at a lower level than an upper surface of the active region 103 under the gate trench 113.

The active region 103 protruding between the isolation layers ISO disposed in the direction in which the gate trench 113 extends, that is, in the first direction, may be referred to as a ‘fin 103F’. See FIG. 2B. The fin 103F may be formed in the active region 103 in contact with the first region R1 of the device isolation layer ISO. The fin 103F may not be formed in the active region 103 in contact with the second region R2 of the device isolation layer ISO. That is, the fin 103F may not formed in the second region R2 of the device isolation layer ISO positioned at the same level as the active region 103 under the gate trench 113, and may have an asymmetric shape that is locally formed only in the first region R1 of the device isolation layer ISO which is positioned at a level lower than the upper surface of the active region 103 under the gate trench 113.

The lower surface of the gate electrode 115 may be lower in the first region R1 of the device isolation layer ISO than in the active region 103 and the second region R2 of the device isolation layer ISO. That is, in the first region R1 of the device isolation layer ISO in which word line interference between neighboring cells does not occur, the channel length may be sufficiently secured by a fin 103F as the bottom surface of the gate electrode 115 is positioned at a lower level than in the active region 103. Accordingly, the driving current of the transistor may be increased and the operating characteristics may be improved. In addition, in the second region R2 of the device isolation layer ISO, the area of the passing gate decreases as much as the height of the device isolation layer ISO, thereby preventing word line interference between neighboring cells (Row Hammer). Here, the passing gate refers to a word line WL formed in the device isolation layer ISO between adjacent active regions 103 spaced apart from each other in the long axis direction.

A first impurity region 117 and a second impurity region 118 serving as a source and a drain of the transistor may be formed in the active region 103 on both sides of the gate structure BG. The first impurity region 117 may be electrically connected to the bit line BL, and the second impurity region 118 may be electrically connected to the capacitor CAP. The bit line BL and the first impurity region 117 may be electrically connected to each other by a bit line contact plug BLC. The capacitor CAP and the second impurity region 118 may be electrically connected to each other by a storage contact plug SNC.

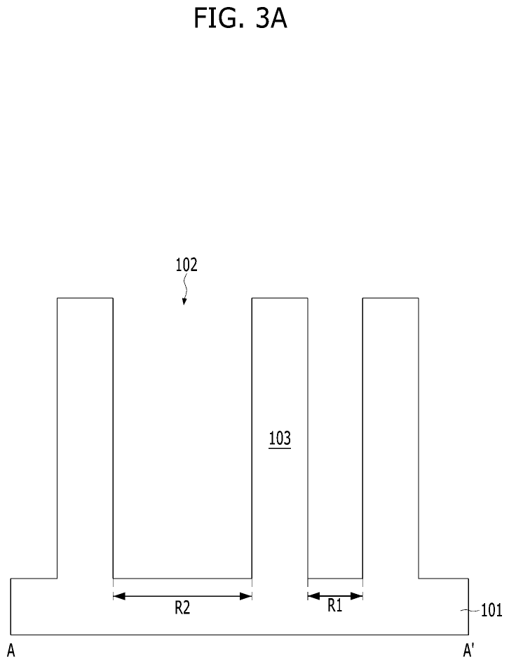

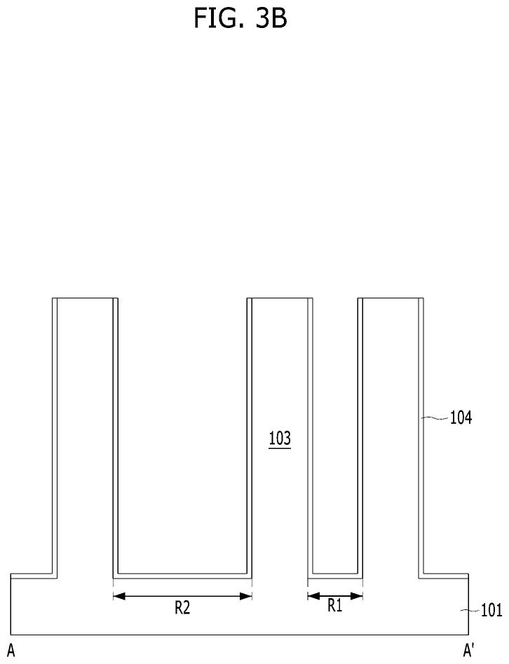

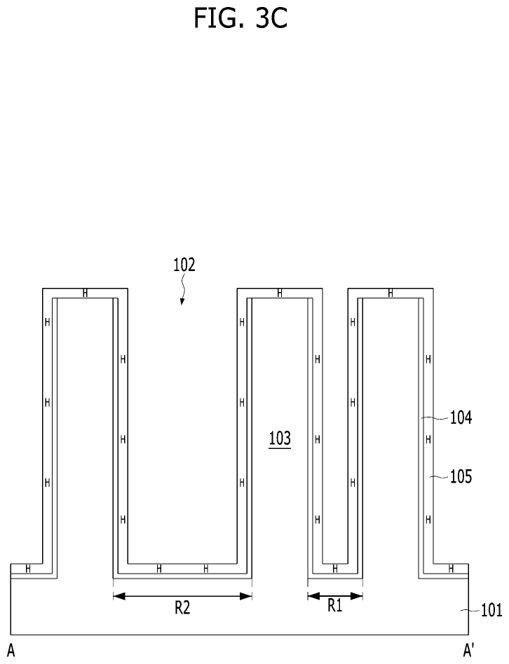

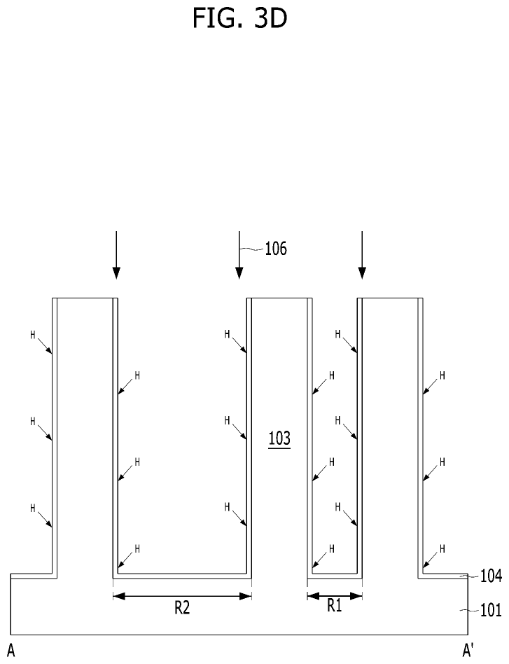

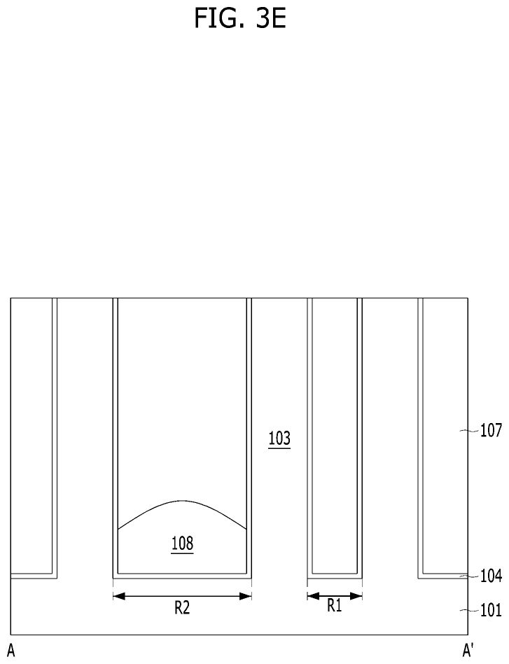

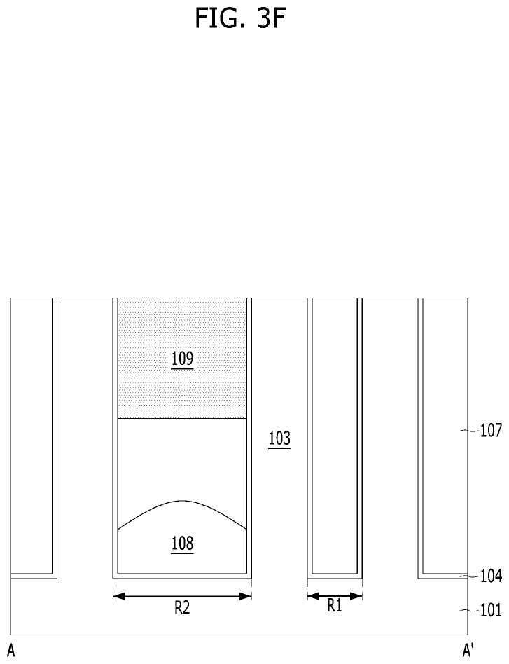

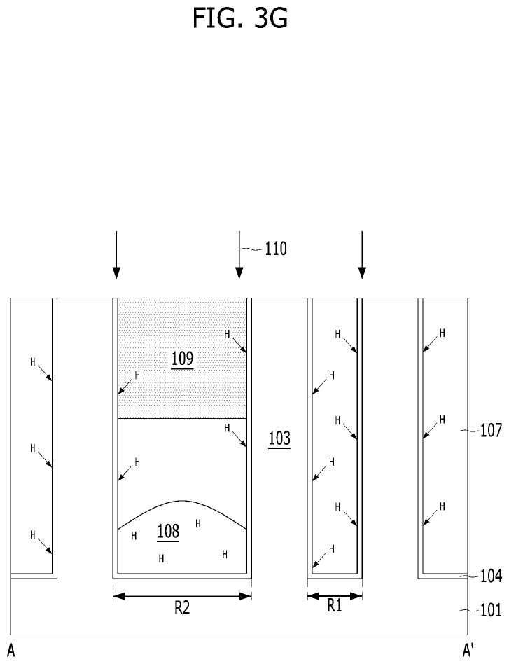

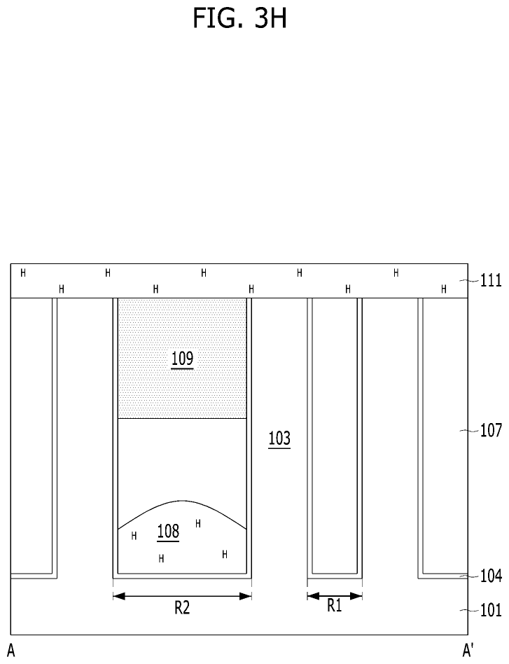

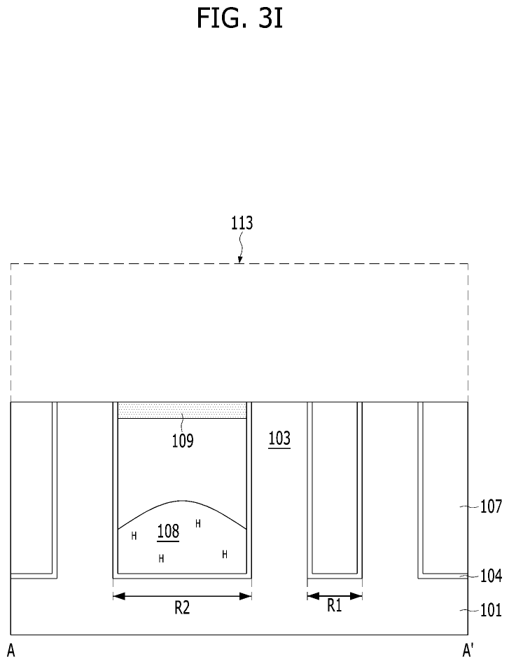

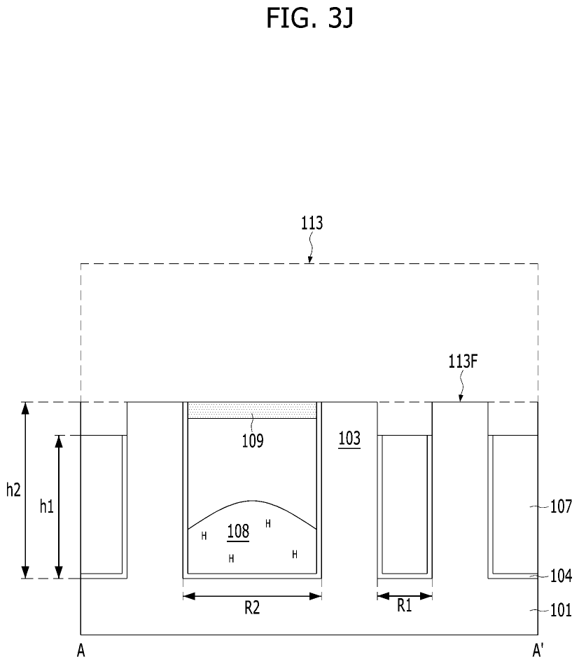

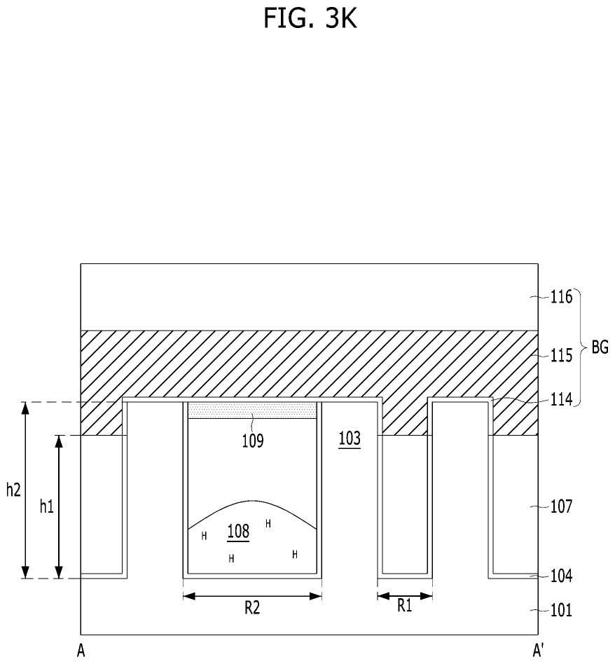

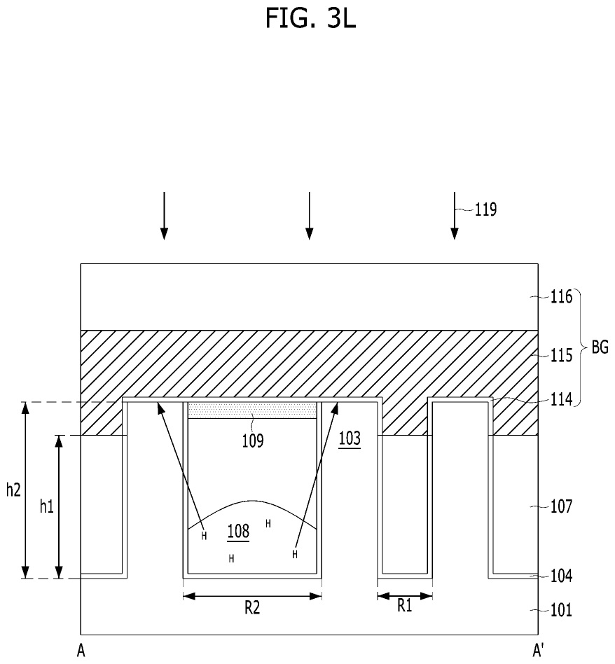

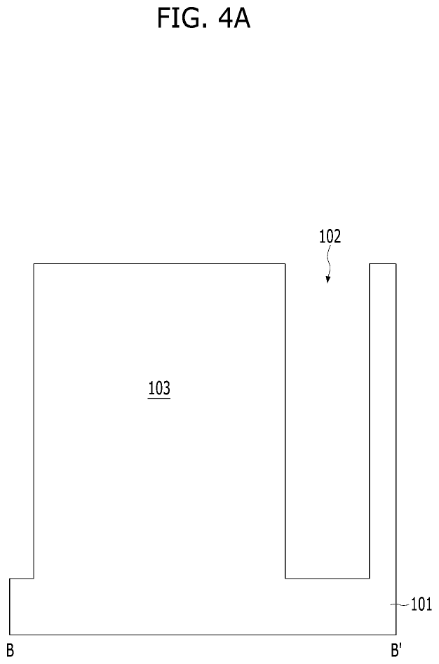

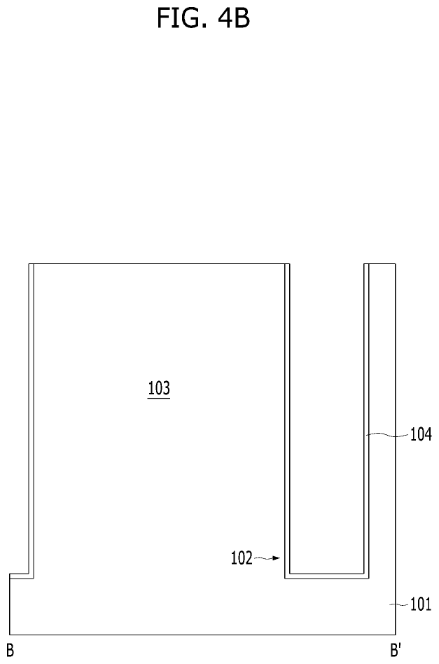

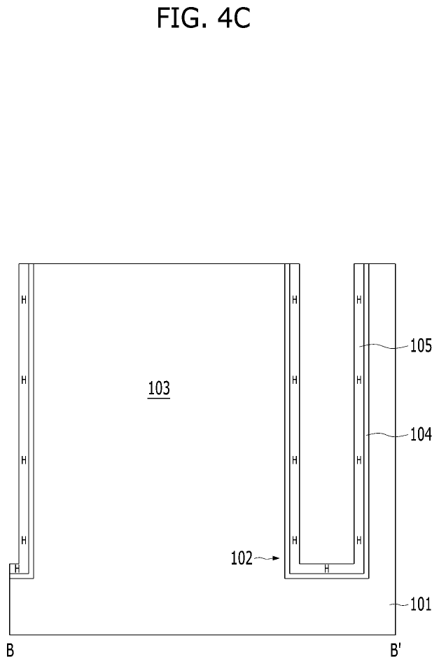

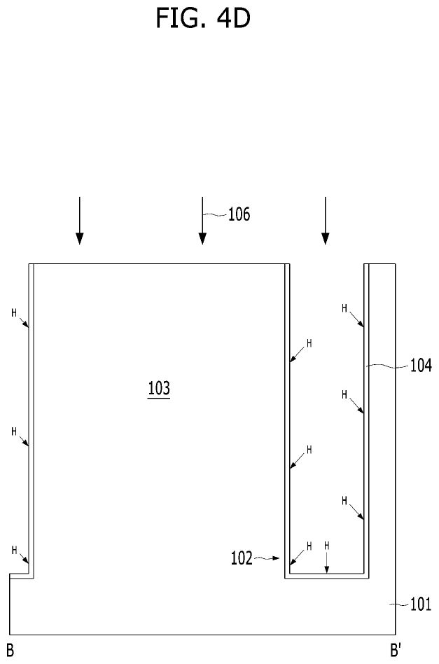

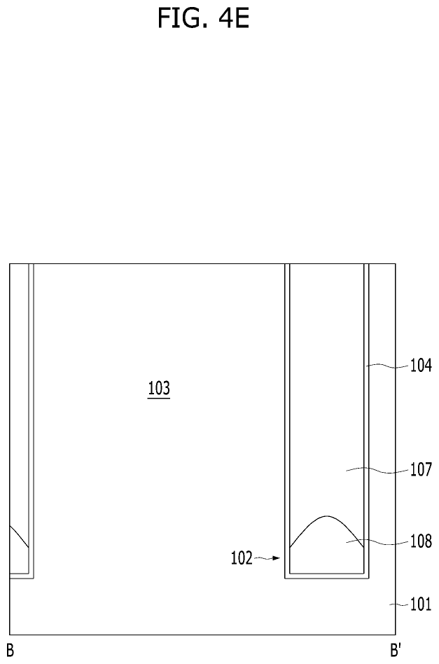

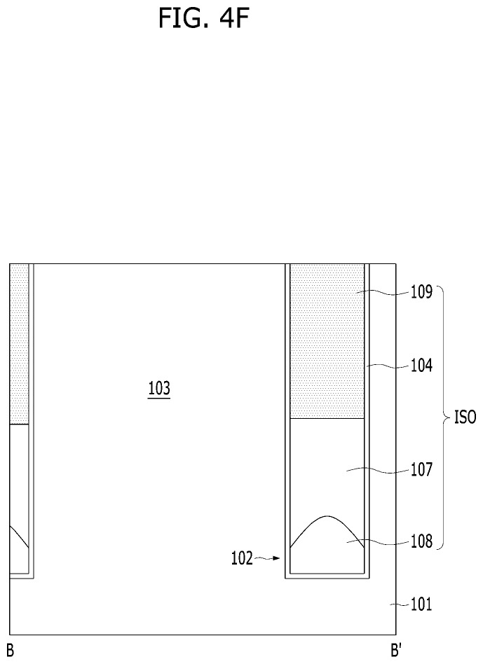

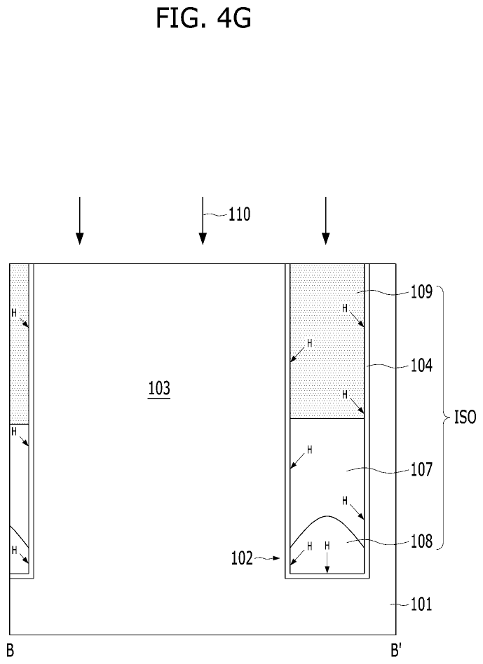

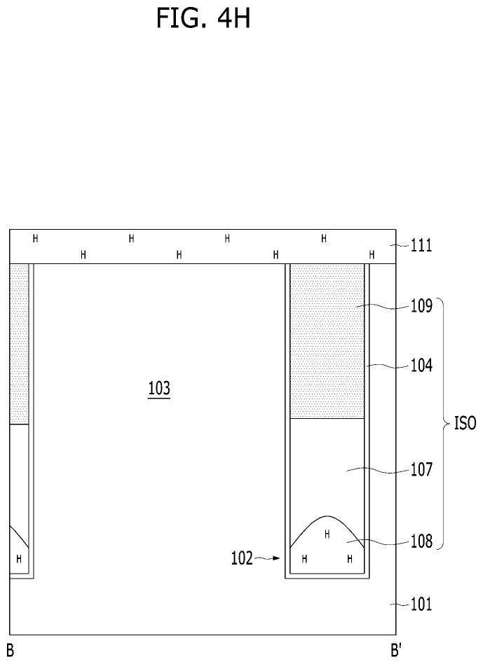

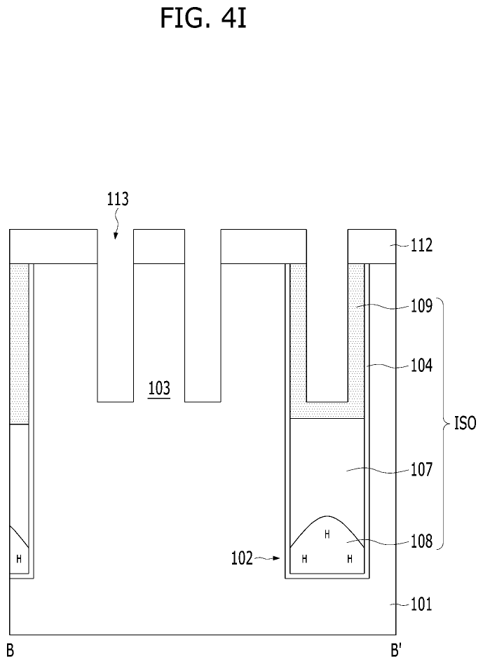

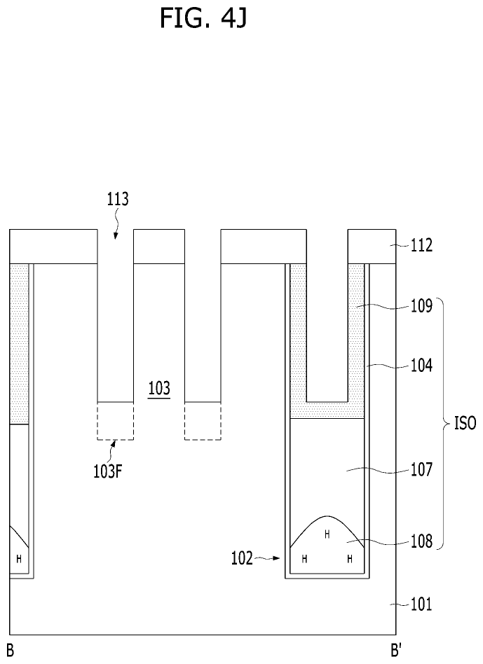

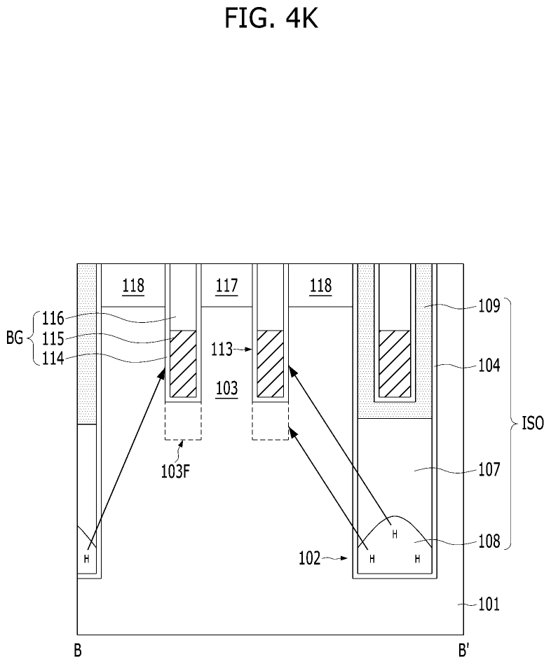

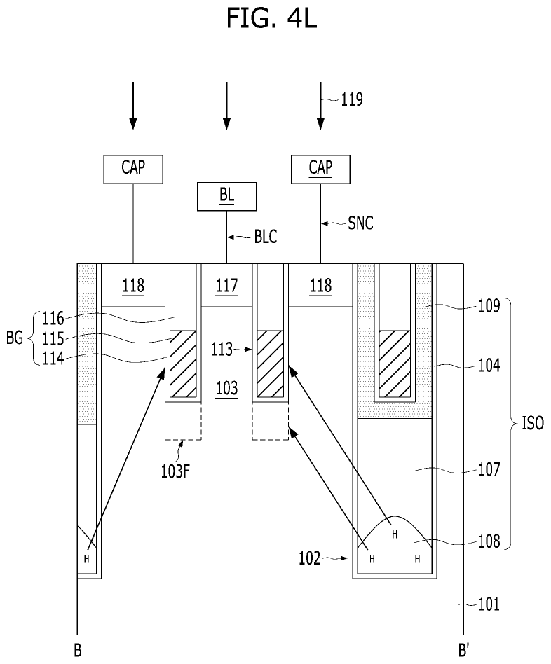

FIGS. 3A to 3L are cross-sectional views illustrating a method of fabricating a semiconductor device taken along line A-A′ of FIG. 1. FIGS. 4A to 4L are cross-sectional views illustrating a method of fabricating a semiconductor device taken along line B-B′ of FIG. 1.

As shown in FIGS. 1, 3A and 4A, an isolation trench 102 defining the active region 103 may be formed in the substrate 101.

The substrate 101 may be a material suitable for semiconductor processing. The substrate 101 may include a semiconductor substrate. The substrate 101 may be made of a material containing silicon. The substrate 101 may include silicon, monocrystalline silicon, polysilicon, amorphous silicon, silicon germanium, monocrystalline silicon germanium, polycrystalline silicon germanium, carbon doped silicon, combinations thereof, or multiple layers thereof. The substrate 101 may include other semiconductor materials such as germanium. The substrate 101 may include a III/V group semiconductor substrate, for example, a compound semiconductor substrate such as GaAs. The substrate 101 may include a silicon on insulator (SOI) substrate.

The active region 103 defined by the isolation trench 102 may be formed to have a long axis and a short axis. The active region 103 may be two-dimensionally arranged along the long axis direction and the short axis direction. For example, the active region 103 may have a bar shape having a length longer than a width, and may be arranged in an island shape.

The isolation trench 102 may include a first region R1 in which the active regions 103 are spaced apart at a first interval along the first direction D1 and a second region R2 in which the active regions 103 are spaced apart at a second interval, which is greater than the first interval, in the first direction D1.

As shown in FIGS. 1, 3B and 4B, a liner oxide layer 104 covering sidewalls and a bottom surface of the isolation trench 102 may be formed. For example, the liner oxide layer 104 may include silicon oxide.

As shown in FIGS. 1, 3C and 4C, the first hydrogen supply layer 105 may be formed on the liner oxide layer 104. The first hydrogen supply layer 105 may cover the entire surface of the substrate 101 including the isolation trench 102. The first hydrogen supply layer 105 may include an insulating material containing hydrogen. For example, the first hydrogen supply layer 105 may include high density plasma (HDP) oxide. Furthermore, HDP oxide is an oxide deposited by using high-density plasma, and a large amount of excited hydrogen is generated during the process, so that the amount of hydrogen diffused into the substrate 101 may be improved.

Hydrogen supplied through the process of forming the first hydrogen supply layer 105 may diffuse into the interface between the substrate 101 and the liner oxide layer 104 or into the substrate 101. Hydrogen supplied through the process of forming the first hydrogen supply layer 105 may eliminate the dangling bonds by forming Si—H or Si—OH bonds at the surface of the substrate 101 (e.g., the interface between the substrate 101 and the liner oxide layer 104). Accordingly, it is possible to reduce a trap charge due to a dangling bond.

Next, the first hydrogen supply layer 105 may be removed.

As shown in FIGS. 1, 3D and 4D, a first forming gas annealing (FGA) 106 process may be performed. Forming gas annealing refers to annealing for stabilizing electrical characteristics of a semiconductor device during a fabrication process. For example, the forming gas may include a gas mixture including hydrogen.

As the first forming gas annealing 106 is performed, hydrogen is diffused into the interface between the substrate 101 and the liner oxide layer 104 or into the substrate 101. Hydrogen supplied through the first forming gas annealing 106 can eliminate dangling bonds by forming Si—H or Si—OH bonds at a surface of the substrate 101 (e.g., the interface between the substrate 101 and the liner oxide layer 104). Accordingly, it is possible to reduce a trap charge due to a dangling bond.

As shown in FIGS. 1, 3E, and 4E, a gap-fill oxide layer 107 for gap-filling the isolation trench 102 may be formed on the liner oxide layer 104. The gap fill oxide layer 107 may include a material having a lower step coverage than the liner oxide layer 104. The gap fill oxide layer 107 may include silicon oxide. For example, the gap fill oxide layer 107 may include tetraethylortho silicate (TEOS) oxide.

The first region R1 of the isolation trench 102 may be fully gap-filled with the gap-fill oxide layer 107. An air gap 108 may be formed under the second region R2 of the isolation trench 102 by the step coverage of the gap fill oxide layer 107.

As shown in FIGS. 1, 3F and 4F, an isolation capping layer 109 may be formed on the second region R2 of the isolation trench 102.

First, the gap-fill oxide layer 107 may be recessed to a predetermined thickness in the second region R2 of the isolation trench 102. The recess process may be performed under a condition that only the gap-fill oxide layer 107 gap-filled in the second region R2 is selectively recessed. Next, an insulating material may be formed on the gap-fill oxide layer 107 of the second region R2 to gap-fill the remainder of the isolation trench 102, and a planarization process may be performed to form the isolation capping layer 109. For example, the isolation capping layer 109 may include silicon nitride.

Accordingly, the device isolation layer ISO including the gap-fill oxide layer 107 may be formed in the first region R1 of the isolation trench 102, and the device isolation layer ISO having a stacked structure of the air gap 108, a gap-fill oxide layer 107, and an isolation capping layer 109 may be formed from the bottom of the isolation trench 102 in the second region of the isolation trench 102.

As shown in FIGS. 1, 3G and 4G, a second forming gas annealing (FGA) 110 process may be performed.

Hydrogen supplied through the second forming gas annealing 110 process may diffuse to the interface between the substrate 101 and the liner oxide layer 104 or may be trapped in the air gap 108. That is, as the hydrogen supplied through the second forming gas annealing 110 process diffuses into the substrate 101, it moves into the air gap 108 having a relatively large amount of space and is trapped therein. Thus, the air gap 108 may function as a hydrogen pocket storing hydrogen.

As shown in FIGS. 1, 3H and 4H, the second hydrogen supply layer 111 covering the entire surface of the substrate 101 including the device isolation layer ISO may be formed. The second hydrogen supply layer 111 may include an insulating material containing hydrogen. For example, the second hydrogen supply layer 111 may include high density plasma (HDP) oxide. Furthermore, HDP oxide is an oxide deposited using high-density plasma, and a large amount of excited hydrogen is generated during the process, so that the amount of hydrogen diffused into the substrate 101 may be improved.

The hydrogen which is supplied through the process of forming the first hydrogen supply layer 105 is trapped at the interface between the substrate 101 and the liner oxide layer 104 or in the air gap 108.

Subsequently, the second hydrogen supply layer 111 is removed.

As shown in FIGS. 1, 3I and 4I, a hard mask layer 112 defining a gate region may be formed on the substrate 101. In order to pattern the hard mask layer 112, a series of etching processes of forming a mask pattern on the hard mask layer 112 and etching the hard mask layer 112 by using the mask pattern as an etching mask may be performed. The hard mask layer 112 may include an insulating material having an etch selectivity with respect to the device isolation layer ISO and the substrate 101.

Subsequently, the substrate 101 may be etched to form the gate trench 113. The gate trench 113 may have a line shape crossing the active regions 103 and the device isolation layer ISO.

As shown in FIGS. 1, 3J, and 4J, the device isolation layer ISO may be additionally recessed. The recess process may be performed under a condition having an etch selectivity with respect to the isolation capping layer 109 and the substrate 101. Accordingly, the bottom surface of the gate trench 113 positioned in the first region R1 of the device isolation layer ISO may be positioned at a lower level than the bottom surface of the gate trench 113 positioned in the second region R2 of the device isolation layer ISO and the bottom surface of the gate trench 113 positioned at the active region 103.

The active region 103 is protruding between the device isolation layers ISO which are disposed in the first direction D1 in which the gate trench 113 extends, that is, in the first direction, and the protrusion is referred to as ‘fin 103F’. The fin 103F may be formed in the active region 103 in contact with the first region R1 of the device isolation layer ISO. The fin 103F may not be formed in the active region 103 in contact with the second region R2 of the device isolation layer ISO. That is, the fin 103F is not formed in the second region R2 of the device isolation layer ISO positioned at the same level as the active region 103 under the gate trench 113, and may have an asymmetric shape that is locally formed only in the first region R1 of the device isolation layer ISO which is positioned at a level lower than the upper surface of the active region 103 under the gate trench 113.

As shown in FIGS. 1, 3K and 4K, a buried gate structure BG may be formed to gap-fill the gate trench 113.

The buried gate structure BG may include a gate insulating layer 114 covering the surface of the gate trench 113 including the fin 103F, a gate electrode 115 gap-filling a portion of the gate trench 113 on the gate insulating layer 114, and a gate capping layer 116 gap-filling the remainder of the gate trench 113 on the gate electrode 115.

The gate insulating layer 114 may be formed by thermal oxidation. For example, the gate insulating layer 114 may be formed by oxidizing the bottom and sidewalls of the gate trench 113.

In another embodiment, the gate insulating layer 114 may be formed by a deposition method such as chemical vapor deposition (CVD) or atomic layer deposition (ALD). The gate insulating layer 114 may include a high-k material, oxide, nitride, oxynitride, or a combination thereof. The high-k material may include hafnium oxide. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, and combinations thereof. In another embodiment, the gate insulating layer 114 may be formed by depositing liner polysilicon and then radically oxidizing the liner polysilicon layer. In another embodiment, the gate insulating layer 114 may be formed by radically oxidizing the liner silicon nitride layer after forming the liner silicon nitride layer.

The gate electrode 115 may include a conductive material. To form the gate electrode 115, a recessing process may be performed after a conductive layer is formed to fill the gate trench 113. The recessing process may be performed as an etchback process, or a chemical mechanical polishing (CMP) process and an etchback process may be sequentially performed. The gate electrode 115 may have a recessed shape that partially fills the gate trench 113. That is, the upper surface of the gate electrode 115 may be at a lower level than the upper surface of the substrate 101. The gate electrode 115 may include a metal, a metal nitride, or a combination thereof. For example, the gate electrode 115 may be formed of a titanium nitride (TiN), tungsten (W), or a titanium nitride/tungsten (TiN/W) stack. The titanium nitride/tungsten (TiN/W) stack may include titanium nitride which is first conformally formed in the gate trench 113 and then the tungsten is partially filled in the gate trench 113. In an embodiment, the gate electrode 115 is formed solely from titanium nitride, and this embodiment is referred to hereinafter as a “TiN only” gate electrode structure. In another embodiment, the gate electrode 115 includes a double gate structure of a titanium nitride/tungsten (TiN/W) stack and a polysilicon layer.

The gate capping layer 116 includes an insulating material. For example, the gate capping layer 116 may include silicon nitride. In another example, the gate capping layer 116 may include silicon oxide. In yet another example, the gate capping layer 116 may have a nitride-oxide-nitride (NON) structure.

Subsequently, first and second impurity regions 117 and 118 may serve as a source and a drain of the transistor and may be formed in the active region 103 on both sides of the gate structure BG. For example, the first and second impurity regions 117 and 118 may be formed by a doping process such as implantation. The first and second impurity regions 117 and 118 are also referred to as ‘source/drain regions’.

FIGS. 1, 3L and 4L, illustrate a bit line BL and a capacitor CAP sequentially formed on substrate 101.

The first impurity region 117 is electrically connected to the bit line BL. The second impurity region 118 is electrically connected to the capacitor CAP. The bit line BL and the first impurity region 117 are electrically connected to each other via, for example, a bit line contact plug BLC. The capacitor CAP and the second impurity region 118 may be electrically connected to each other by a storage contact plug SNC.

A metal wiring process may be performed on the capacitor CAP for forming a metal wire and a hydrogen supply layer may be formed on the metal wire.

Subsequently, a hydrogen passivation process 119 may be performed. The hydrogen passivation process 119 supplies hydrogen to the surface of the substrate 101 for repairing surface defects such as dangling bonds.

Generally, during a manufacturing process of a semiconductor device, defects may be generated in a unit element of the semiconductor device. For example, defects in a unit element may appear during an oxidation process, a plasma etching process, and like processes. These defects alter the electrical characteristics of the semiconductor device. For example, generally, dangling bonds may form at the interface between the silicon oxide layer and the silicon substrate of a unit element and between the gate insulating layer and the substrate, which increase leakage current and deteriorate the electrical characteristics of the semiconductor device. In the case of a dynamic random-access memory (DRAM) semiconductor device, it is necessary to re-store the existing data at regular intervals by using a refresh method for storing new data. In this case, the predetermined period is referred to as a refresh period or a data retention time. In order to reduce the power consumption of the DRAM and increase the operation speed, it is required to increase the data retention time. However, due to a structural defect in the silicon crystal such as a dangling bond, a leakage current may increase in the transistors and a data retention time may also be reduced.

In this embodiment, during the hydrogen passivation process, hydrogen stored in the air gap 108 in the device isolation layer ISO diffuses to the interface between the substrate 101 and the gate insulating layer 114, and dangling bonds may be eliminated by forming Si—H or Si—OH bonds at an interface between the substrate 101 and the gate insulating layer 114. Therefore, the efficiency of the hydrogen passivation process may be maximized compared to when the hydrogen passivation process is performed by using only the hydrogen supply layer above the metal wiring.

Various embodiments of the present invention have been described which fall within the scope of the present invention and solve the aforementioned problems associated with the prior art, however, the present invention is not limited to these embodiments only. It should be apparent to those skilled in the art that various other changes and modifications could be made within the technical scope and spirit of the present invention.

What is claimed is:

1. A semiconductor device comprising:
a device isolation layer defining a plurality of active regions in a substrate, the device isolation layer including a first region where the active regions are spaced apart from each other at a first interval along a first direction and a second region where the active regions are spaced apart from each other at a second interval along the first direction, the second interval being wider than the first interval;
a gate trench extending in the first direction to cross the active regions and the device isolation layer; and
a buried gate structure gap-filling the gate trench,
wherein the second region of the device isolation layer includes an air gap in a lower portion.

2. The semiconductor device of claim 1, wherein the air gap is positioned at a lower level than the buried gate structure.

3. The semiconductor device of claim 1, wherein a bottom surface of the gate trench in the first region of the device isolation layer is positioned at a lower level than a bottom surface of the gate trench in the second region of the device isolation layer.

4. The semiconductor device of claim 1, wherein a bottom surface of the gate trench in the first region of the device isolation layer is positioned at a lower level than a bottom surface of the gate trench in the active region.

5. The semiconductor device of claim 1, wherein a bottom surface of the gate trench in the second region of the device isolation layer is positioned at a lower level than a bottom surface of the gate trench in the active region.

6. The semiconductor device of claim 1, wherein the device isolation layer has different insulating structures in the first region and the second region.

7. The semiconductor device of claim 1, wherein the device isolation layer of the first region includes a gap-fill oxide layer.

8. The semiconductor device of claim 1, wherein the device isolation layer of the second region includes a stacked structure including the air gap, a gap-fill oxide layer, and an isolation capping layer.

9. The semiconductor device of claim 8, wherein the gap-fill oxide layer includes silicon oxide.

10. The semiconductor device of claim 8, wherein the isolation capping layer includes silicon nitride.

11. A semiconductor device comprising:
a substrate including a device isolation layer and an active region defined by the device isolation layer;
a gate trench formed both in the active region and the device isolation layer; and
a buried gate structure gap-filling the gate trench,
wherein the device isolation layer includes an air gap disposed at a lower level than the buried gate structure.

12. A method of fabricating a semiconductor device, the method comprising:
forming a device isolation layer defining a plurality of active regions in a substrate, the device isolation layer including a first region where the active regions are spaced apart from each other at a first interval along a first direction and a second region where the active regions are spaced apart from each other at a second interval along the first direction, the second interval being wider than the first interval;
forming a gate trench extending in the first direction to cross the active regions and the device isolation layer; and
forming a buried gate structure gap-filling the gate trench,
wherein the second region of the device isolation layer includes an air gap in a lower portion.

13. The method of claim 12, after the forming of the device isolation layer, further including:
performing forming gas annealing.

14. The method of claim 13, wherein the performing of forming gas annealing uses a gas mixture including hydrogen.

15. The method of claim 12, after the forming of the device isolation layer, further including:
forming a hydrogen supply layer for diffusing hydrogen into an entire surface of the substrate including the device isolation layer by the substrate and the air gap; and
removing the hydrogen supply layer.

16. The method of claim 15, wherein the hydrogen supply layer includes high density plasma (HDP) oxide.

17. The method of claim 12, the forming of the device isolation layer including:
forming an isolation trench defining a plurality of active regions in the substrate;
forming a liner oxide layer covering a sidewall and a bottom surface of the isolation trench;
forming a gap-fill oxide layer, the gap-fill oxide layer forming an air gap in a lower portion of the isolation trench of the second region by gap-filling a portion of the isolation trench of the second region over the liner oxide layer; and
forming an isolation gap-fill layer gap-filling the remainder of the isolation trench of the second region.

18. The method of claim 17, wherein the gap-fill oxide layer fully gap-fills the isolation trench of the first region.

19. The method of claim 17, after the forming of the liner oxide layer, further including:
forming a hydrogen supply layer covering an entire surface of the substrate including the liner oxide layer for diffusing hydrogen into the substrate; and
removing the hydrogen supply layer.

20. The method of claim 17, after the forming of the liner oxide layer, further including:
performing forming gas annealing.

21. The method of claim 12, after the forming of the gate trench, further including:
forming an asymmetric fin by recessing a predetermined depth of the device isolation layer of the first region.

22. The method of claim 12, after the forming of the buried gate structure, further including:
sequentially forming a bit line and a capacitor over the substrate; and
performing a hydrogen passivation process for supplying hydrogen into the substrate.
